(19) United States
(12) Patent Application Publication
(10) Pub. No.: US 2002/0074664 A1
(43) Pub. Date: Jun. 20, 2002

(54) Semiconductor device and manufacturing method thereof

(76) Inventors: Takeshi Nogami, Kanagawa (JP); Naoki Komai, Kanagawa (JP); Hideyuki Kito, Kanagawa (JP); Mitsuru Taguchi, Tokyo (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 09/915,145

(22) Filed: Jul. 25, 2001

(30) Foreign Application Priority Data
Jul. 26, 2000 (JP) P2000-224884

(51) Int. Cl. H01L 23/48; H01L 23/52; H01L 29/40

(52) U.S. Cl. 257/764

(57) ABSTRACT

On a copper wiring surface, an oxidation resistive and fluorinated acid resistive layer is formed, and an oxidation resistive copper wiring, enhancement of resistive fluorinated acid nature are achieved. Furthermore, a via-hole connection resistance is reduced, and a clad layer (the CoWP layer) having oxidation resistive and fluorinated acid resistive nature high copper wiring configuration is formed, and cover layer (the CoWP layer) including cobalt and the CoWP layer of reliability, and the CoWP layer is formed by the copper wiring.

### RELATED APPLICATION DATA

The present application claims priority to Japanese Patent Application No. P2000-224884 filed Jul. 26, 2000, which application is incorporated by reference to the extent permitted by law.

### BACKGROUND OF THE INVENTION

1. Field of the Invention

The present invention relates to a method for manufacturing a semiconductor device having copper wiring comprising an oxidation resistive and a fluorinated acid resistive layer.

2. Related Art

It is proposed to use a CoWP (cobalt tungsten phosphor) film in order to prevent oxidation of copper. It is well known that in a manufacturing method thereof, a palladium layer is formed on a copper surface as a catalytic layer by substitution electro-less plating, then the CoWP layer is formed by a CoWP electro-less plating with the palladium layer as a catalytic layer.

The CoWP film has diffusion barrier characteristics to the copper, and is formed, for example, in a course of a damascene process for forming the copper wiring.

For example, as shown in FIG. 4, a wiring groove 112 is formed in an electric insulation film 111 by a desired shape. A copper film accumulated on the electrical insulation film 111 is buried in the wiring groove 112 by way of the barrier layer 113. In addition, an excess copper film on the electrical insulation film 111 is removed by means of a CMP (Chemical Mechanical Polishing). As thus described, a copper wiring 114 is formed in the wiring groove 112 on the barrier layer 113.

Generally, the copper is easily oxidized in an atmosphere including oxygen even in a lower temperature of 150 degrees. Therefore, it is difficult to form an insulating layer directly on a copper surface without oxidizing the cupper, where the insulating layer may include a silicon oxide film that employs an oxygen as a reaction gas.

Thus the oxidation of the cupper is generally prevented by coating an anti-oxidization film such as a silicon nitride film or a silicon carbide film formed by a CVD (Chemical Vapor Deposition) without oxygen. However, a dielectric constant of the silicon nitride film is 8 and a dielectric constant of the silicon carbide film is 5, and accordingly both dielectric constant are high, so that it is not proper to apply to a wiring system using the copper wiring being expected its low resistance and low capacity, because it results to raise a whole parasitic capacitance.

It is proposed that as a method for solving this problem, a CoWP layer 115 is selectively formed on a surface of the copper wiring 114 by the electro-less plating as shown in FIG. 5 as to protect an easily oxidizing copper surface, and after that a forming process for the insulating film such as a silicone oxide layered with oxidizing atmosphere is conducted.

However, in a conventional technique, the CoWP layer is eroded by a fluorinated acid, and therefore in a case where a fluorinated acid treatment is applied for the purpose of removing copper atoms residing on a surface of an unwrapped insulating film among the copper wiring, it causes a problem that the CoWP layer is also extinguished by etching. In addition, the CoWP layer is hard to be oxidized in comparison with the copper, however, it is oxidized when exposed in a chemical vapor epitaxy atmosphere for forming a silicon oxide. In this case, a cobalt oxide is formed threby. As a result, when via holes connecting to the copper wiring by forming the CoWP layer are provided, another problem where the cobalt oxide remaining at bottom of the via holes increases a via hole connection resistance is raised.

### SUMMARY OF THE INVENTION

The present invention relates to a semiconductor device and a manufacturing method thereof that is done in order to solve the above-mentioned problems.

The semiconductor device of the present invention comprises a CoWP layer as a cobalt including layer, and a cobalt silicide layer for cladding the cobalt including layer having oxidation resistive and fluorinated acid resistive nature.

In the above mentioned semiconductor device, the CoWP layer as a cobalt including layer is covered with the cobalt silicide layer as a clad layer having oxidation resistance and fluorinated acid resistance, so that the CoWP layer is protected from oxidizing atmosphere and fluorinated acid atmosphere (solution) by the cobalt silicide layer. Further, the CoWP layer is effective as a diffusion preventing film of copper, so that the diffusion of copper is prevented by forming a lamination structure of the CoWP layer and the cobalt silicide layer on the copper wiring, and as a result, the diffusion of copper is prevented during the forming process and the wiring structure becomes to be oxidation resistive and fluorinated acid resistive.

A manufacturing method of a semiconductor device of the present invention comprises production process to form on the surface of the CoWP layer a cobalt silicide layer as a cobalt including layer by exposing the CoWP layer in silane system gas.

In the manufacture method of the semiconductor device of above described, a cobalt silicide layer as a cobalt including layer is formed on the surface of the CoWP layer by exposing in the silane system gas. Therefore, the CoWP film or layer is protected from oxidation and corrosion by fluorinated acid owing to the cobalt silicide film. As a result it is not necessary to cover the copper surface with a silicon nitride film or a silicon carbide film. In addition, the process can be introduced as one part of formation process of the silicon oxide film by the CVD method after forming the CoWP film it gets possible to be introduced. Therefore new apparatus is not required, load of the production process is minimized, and a smooth process treatment becomes possible with low cost.

### BRIEF DESCRIPTION OF THE DRAWINGS

In the accompanying drawings:

FIG. 1 is a sectional view showing a preferred embodiment of a semiconductor device of the present invention;

FIG. 2A and FIG. 2B are sectional views showing a preferred embodiment of a manufacture method of the semiconductor device of the present invention;

FIG. 3 is a scheme showing accumulated silicon on an insulation film;

FIG. 4 is a sectional view showing a conventional groove wiring configuration; and

FIG. 5 is a sectional view showing the groove wiring configuration of a conventional CoWP layer.

### DETAILED DESCRIPTION OF THE PREFERRED EMBODIMENTS

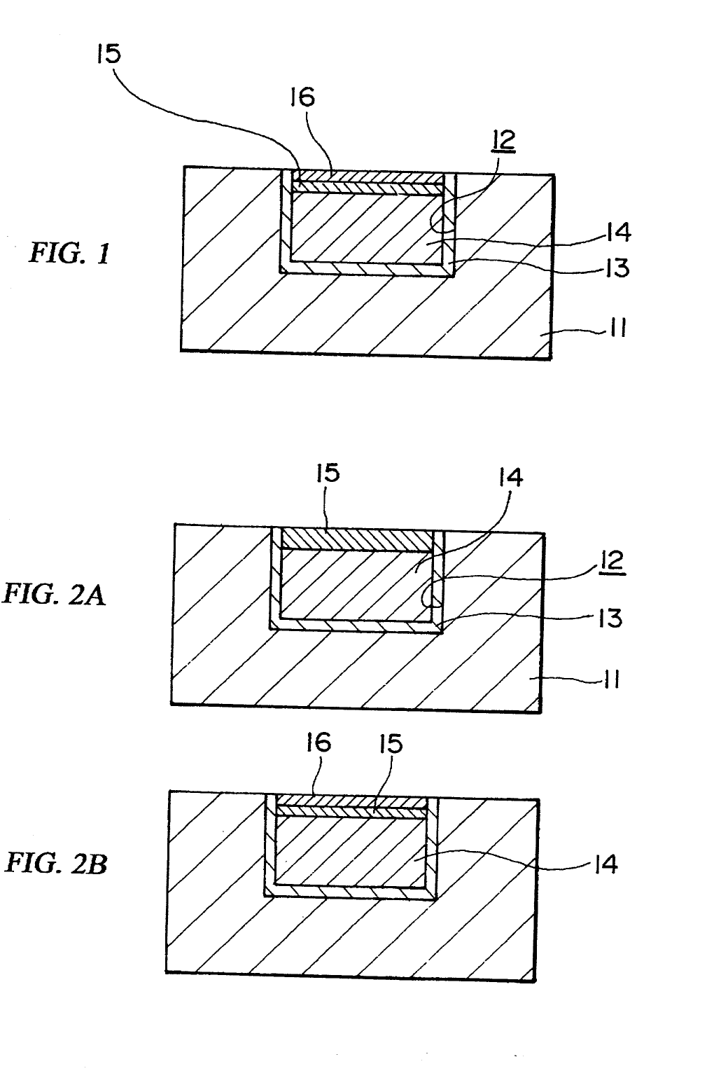

Detailed description of the preferred embodiment related to semiconductor device of the present invention will be explained with reference to FIG. 1. In FIG. 1, a copper wiring of groove wiring configuration is shown as one example.

As shown in FIG. 1, a wiring groove 12 is formed on an insulation film 11 that is formed on the base substrate (not shown). For example, the insulation film 11 is a silicon oxide film. For example, a barrier layer 13 is formed in inside of the wiring groove 12 for preventing diffusion of copper and oxidation of copper, in which the barrier layer 13 is formed with a nitride tungsten film or a tantalum nitride film. Furthermore, a copper wiring 14 is formed on the barrier layer 13 in inside of the wiring groove 12. The copper wiring as mentioned herein means such wiring comprising of copper or such wiring based on copper as a main material.

For example, on surface of the copper wiring 14, a CoWP (cobalt tungsten phosphor) layer is formed as a cobalt including layer 15. Furthermore, for example, cobalt silicide (here in after, it is written as CoSi₂) layer is formed as a clad layer 16 having oxidation resistive and fluorinated acid resistive nature as to cover the CoWP layer 15.

In the semiconductor device having the wiring configuration as described above, the cobalt including layer (CoWP layer) 15 is covered with the clad layer (CoSi₂ layer) 16 having oxidation resistive and fluorinated acid resistive nature, so that the cobalt including layer (CoWP layer) 15 is protected from oxidizing atmosphere and fluorinated acid atmosphere (solution) owing to the clad layer (CoSi₂ layer) 16. On the other hand, the cobalt including layer (CoWP layer) 15 is effective as a diffusion prevention film of the copper wiring 14, and accordingly by forming a lamination structure of the CoWP layer 15 and the CoSi₂ layer 16 on the copper wiring 14, the copper wiring 14 becomes to have oxidation resistive and fluorinated acid resistive nature.

Therefore, the parasitic resistance of the copper wiring 14 is reduced so that it is not necessary to cove the surface of the copper wiring 14 with the silicon nitride film or a silicon carbide film, and accordingly low capacitance can be achieved. In addition, the boundary contacting the copper wiring 14 becomes a boundary of metal and metal such as CoWP and metal. Therefore an electro-migration resistance becomes extremely high because a boundary of insulation film and copper is able to be omitted, wherein such boundary becomes a priority pass for the copper atom.

Detailed description of the preferred embodiment related to a manufacturing method of semiconductor device of the present invention is explained with reference to FIGS. 2A and 2B.

For example, the insulation film 11 is formed with a silicon oxide film by means of a CVD (Chemical Vapor Deposition) method, for example, as shown in FIG. 2A on the base substrate (not shown). Subsequently, by means of a lithograph technology forming a normal resist mask and an etching technology which uses a resist film as an etching mask, the wiring groove 12 is formed on the insulation film 11.

For example, the barrier layer 13 for preventing the diffusion of copper and the oxidation of copper is formed in the inside of the wiring groove 12 with the nitride tungsten film or a tantalum nitride film by means of sputtering for example.

Furthermore, for example, a metal plating seed layer (not shown) is formed by means of a conformal film forming process that is able to form a film such as a chemical vapor growth method or a electro-less plating method.

Then, a copper film to bury the above wiring groove 12 is formed for example, on the insulation film 11 by means of the electric metal plating method. After that, excess copper film on the insulation film 11 and unnecessary barrier layer on the insulation film 11 are removed by means of the chemical mechanical polishing, In this way the copper wiring 14 is formed in the wiring groove 12 by way of the barrier layer 13,

Subsequently, for example, the CoWP layer is formed as the cobalt including layer 15 on the surface of the copper wiring 14 by a displacement plating method with the use of metal catalyst such as palladium catalyst, for example. It is described as the CoWP layer 15 here in after. With such condition, the base substrate is exposed in a reaction gas of silane system such as mono-silane (SiH₄), di-silane (Si₂H₆) and dichloro-silane (SiCl₂H₂).

As a result, the reaction gas and the cobalt in the CoWP film 15 are reacted on the surface of the CoWP film 15 and the clad layer (CoSi₂ layer) 16 is formed as shown in FIG. 2B. Here in after it is described CoSi₂ 16. In other words the surface of the copper wiring 14 is covered with a two-layer type cover film of the CoSi₂ layer 16 and the CoWP layer 15.

As for the CoSi₂ film, it is hard to be oxidized in comparison with the CoWP film. Therefore, even the next process using atmosphere including an oxygen is conducted, such as the CVD production process to form a silicon oxide film are done by the next production process, the CoSi₂ film 16 is not oxidized.

Therefore, the copper wiring 14 covered with the CoSi₂ layer 16/the CoWP layer 15 is not oxidized. As a result a problem of high resistance by interposition of cobalt oxide of via resistance is solved. In addition, the CoSi₂ layer 16 is not etched by the fluorinated acid. Therefore, even if production process to expose the base substrate to fluorinated acid for the purpose of removing copper atom existed on the insulation film 11 of a silicon oxide is conducted, the CoWP layer 15 covered by the CoSi₂ 16 is not removed by etching. In this way the oxidation problems in the prior art, such as for example etching by fluorinated acid are solved, so that the CoWP layer 15 covers by means of the CoSi₂ 16.

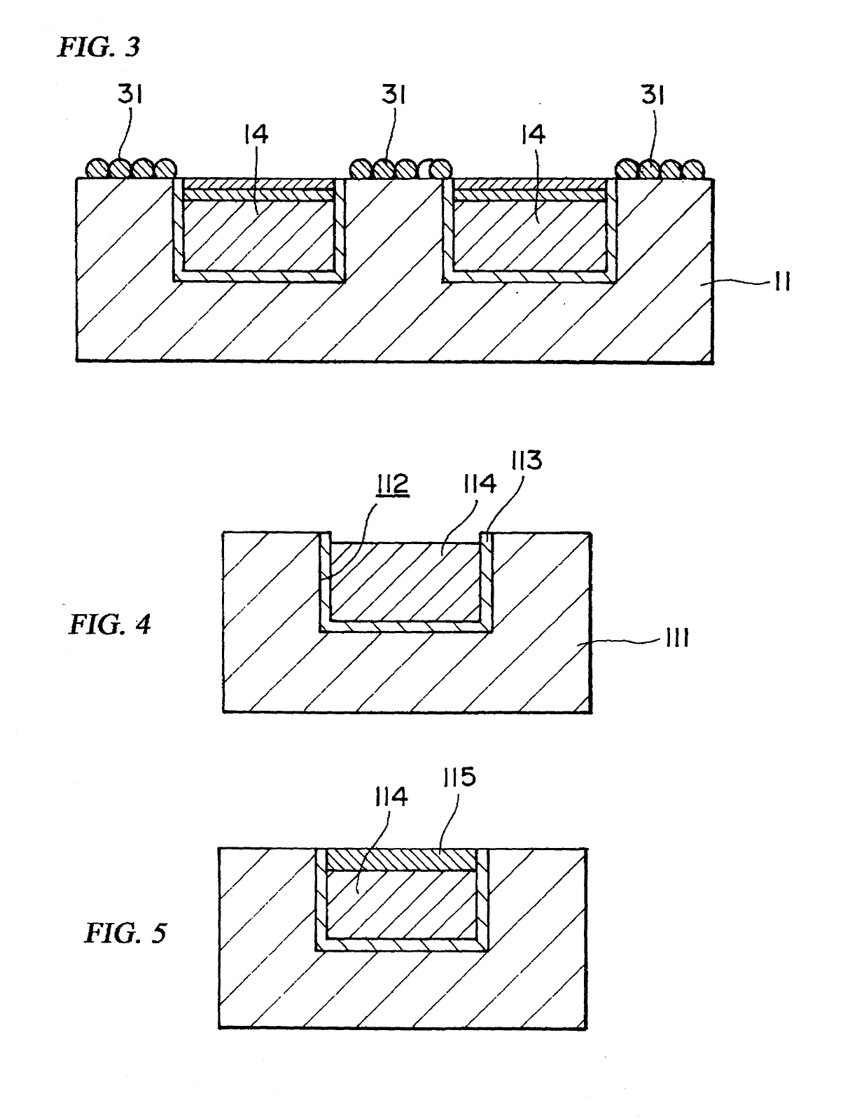

In addition, when, as shown in FIG. 3, the base substrate is exposed into a reaction gas of silane system such as mono-silane (SiH₄), disilane (Si₂H₆), dichlorosilane (SiCl₂H₂), depending on a substrate temperature, density of reaction gas, and exposure time, there is a case in which a pile of a silicon 31 is formed on the insulation film 11 such as silicon oxide films. The silicon 31 piled as described above affects an electric conductivity between the copper wiring 14, 14, so that the electrical insulation nature is tend to be deteriorated.

Thus in the manufacture method of the present invention, the base substrate is exposed to the reaction gas of silane system such as mono-silane (SiH₄), disilane (Si₂H₆), dichlorosilane (SiCl₂H₂), the substrate temperature, pressure of reaction gas are selected in the condition at which the silicon do not pile. Because of this, the pile of the silicon is evaded.

In addition, the formation process of the CoSi₂ layer 16 using silane system gas is possible to introduce as a part of forming process for the silicone oxide film following the process for the CoWP layer 15 by the CVD method.

In other words, the silane system gas is introduced in a chamber of the CVD apparatus which accepts the base substrate, for example, and the base substrate is hated up to a predetermined temperature, thereby the the CoSi₂ layer 16 is selectively formed on is the surface of the CoWP layer 15. Sedimentation of the silicon oxide film can be done in the same chamber, afterwards. Therefore, without the need for new apparatus, load of production process is minimized, and smooth process treatment is able to be achieved with low cost.

As described above, the CoWP film 15 is covered with the CoSi₂ layer 16, so that the CoWP layer 15 is prevented from oxidation and corrosion by the fluorinated acid owing to the CoSi₂ layer 16.

As a result, parasitic resistance of the copper wiring 14 is reduced so that it is not necessary to cover the copper wiring 14 with a silicon nitride film or a silicon carbide film, and low capacitance can be expected. In addition, the boundary contacting the copper wiring 14 comes in contact with the boundary of metal to metal named the CoWP to copper boundary. Therefore the electro migration resistance becomes extremely high in order to be able to get the electrical insulation of film to copper boundary that has priority diffusion pass of copper atom.

What is claimed is:

1. A semiconductor device comprising:
a cobalt including layer having oxidation resistive and fluorinated acid resistive; and
a clad layer for cladding said cobalt including layer.

2. The semiconductor device as cited in claim 1, wherein
said cobalt including layer comprising of the cobalt tungsten phosphor layer.

3. The semiconductor device as cited in claim 1, wherein
said clad layer comprising of a cobalt silicide layer.

4. The semiconductor device as cited in claim 1, wherein
said cobalt including layer being formed on a copper wiring face.

5. A method for manufacturing a semiconductor device comprising the steps of:
forming a cobalt including layer; and
forming a cobalt silicide layer on said surface of the cobalt including layer.

6. The method as cited in claim 5, wherein
said cobalt silicide layer being formed by exposing said cobalt including layer in a silane system gas.

7. The method as cited in claim 5, wherein
said cobalt including layer is a cobalt tungsten phosphor layer.
